(19) United States
(12) Patent Application Publication
(10) Pub. No.: US 2014/0099163 A1
(43) Pub. Date: Apr. 10, 2014

(54) CLAMPING COMPONENT AND ELECTRONIC DEVICE USING THE SAME

(71) Applicants: Chih-Hung Chuang, Taipei City (TW); Fu-Sheng Kao, Taipei City (TW); Shin-Min Lee, Taipei City (TW); Chih-Ho Hsieh, Taipei City (TW)

(72) Inventors: Chih-Hung Chuang, Taipei City (TW); Fu-Sheng Kao, Taipei City (TW); Shin-Min Lee, Taipei City (TW); Chih-Ho Hsieh, Taipei City (TW)

(73) Assignee: ASUSTEK COMPUTER INC., Taipei City (TW)

(21) Appl. No.: 14/033,523

(22) Filed: Sep. 23, 2013

Related U.S. Application Data
(60) Provisional application No. 61/711,205, filed on Oct. 8, 2012.

(30) Foreign Application Priority Data
Jul. 1, 2013 (TW) 102123538

(51) Int. Cl. H05K 7/14

(52) U.S. Cl. CPC H05K 7/1401
USPC 403/374.1

(57) ABSTRACT

A clamping component and an electronic device using the same are provided. The clamping component includes a base and a combining portion. The base is disposed at one side of an accommodating space of the body. The combining portion has a obstructing structure and is disposed at the base. The obstructing structure is exposed to the accommodating space. When the second body is received into the accommodating space, the obstructing structure is elastically deformed to against the second body. The clamping component of the disclosure make the two bodies disassembled and assembled without affecting the appearance, and therefore the aesthetic of the two bodies can be maintained, further, the obstructing structure can improve the convenience in assembling the electronic device. In addition, the risk that the second body is detached from the first body under the external shock or a sudden vibration can be reduced via the clamping component.

### CROSS-REFERENCE TO RELATED APPLICATION

This application claims the priority benefits of U.S. provisional application Ser. No. 61/711,205, filed on Oct. 8, 2012 and Taiwan application serial no. 102123538, filed on Jul. 1, 2013. The entirety of each of the above-mentioned patent applications is hereby incorporated by reference herein and made a part of this specification.

### BACKGROUND OF THE INVENTION

1. Field of the Invention

The invention relates to a component and an electronic device and, more particularly, to a clamping component and an electronic device using the same.

2. Description of the Related Art

In recent years, as the technology industry develops, the electronic devices such as a notebook computer, a tablet computer or a mobile phone have been frequently used in daily life. The electronic devices are very popular due to their practicability and convenience.

Furthermore, many electronic devices become diversified, for example, the electronic devices can be integrated into a detachable electronic combination device to improve the practicality, convenience and portability. For example, an electronic combination device, such as a tablet computer equipped with a mobile phone would meet the requirements of data inputting, internet accessing and communication for users.

Currently, a structure such as a hook, a card slot, and a latch can be used to combine two electronic devices. However, an opening or a protrusion may be left on the surface of the electronic device which lowers the aesthetic values. In addition, the structure mentioned above would make the structure of the two electronic devices complex, and thereby improves the manufacture costs.

### BRIEF SUMMARY OF THE INVENTION

A clamping component including a base and a combining portion is provided. The base is disposed at one side of an accommodating space of a first body. The combining portion has a obstructing structure and is disposed at the base, and the obstructing structure is elastically deformed to against a second body.

An electronic device including a first body, a second body and a plurality of the clamping components is further provided. The first body includes an accommodating space and the second body is received into the accommodating space. The clamping components are disposed at the opposite sides of the accommodating space, respectively. Each clamping component comprises a base and a combining portion. The base is disposed at one side of the accommodating space. The combining portion has a obstructing structure and is disposed at the base, and the obstructing structure is elastically deformed to against the second body.

These and other features, aspects and advantages of the disclosure will become better understood with regard to the following embodiments and accompanying drawings.

### BRIEF DESCRIPTION OF THE DRAWINGS

FIG. 1 is an exploded view showing an electronic device in an embodiment of the disclosure.

FIG. 2 is a front view showing the electronic device in FIG. 1.

FIG. 3 is a perspective view showing the clamping component in FIG. 1.

FIG. 4A to FIG. 4B are flowcharts showing the second body and the clamping component are assembled in FIG. 1.

FIG. 5 is an exploded view showing the first body in FIG. 1.

FIG. 6 is an enlarged view of a portion A in FIG. 5.

FIG. 7 is a front view showing the clamping component in FIG. 2.

### DETAILED DESCRIPTION OF THE EMBODIMENTS

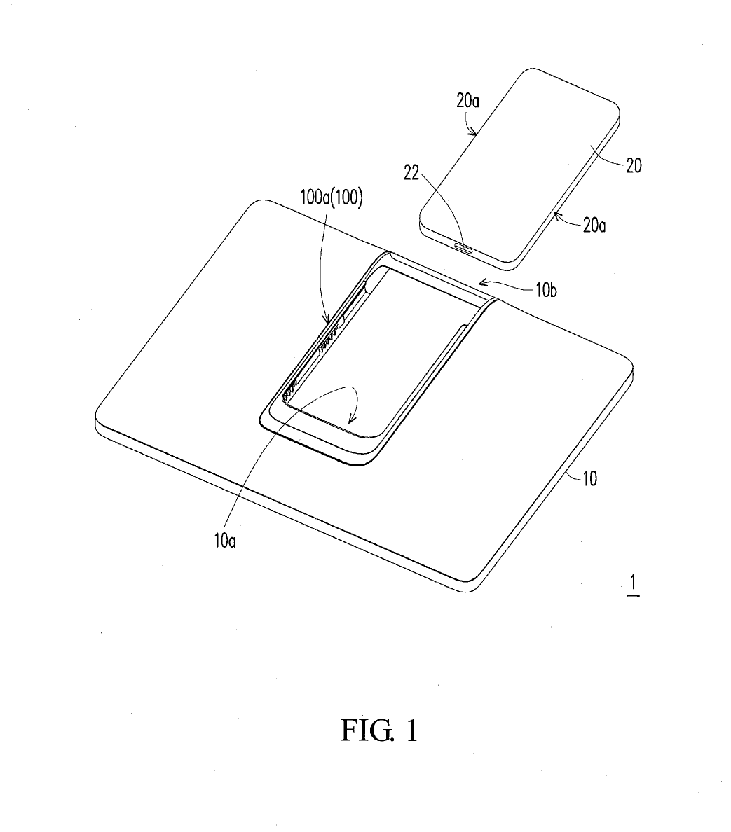

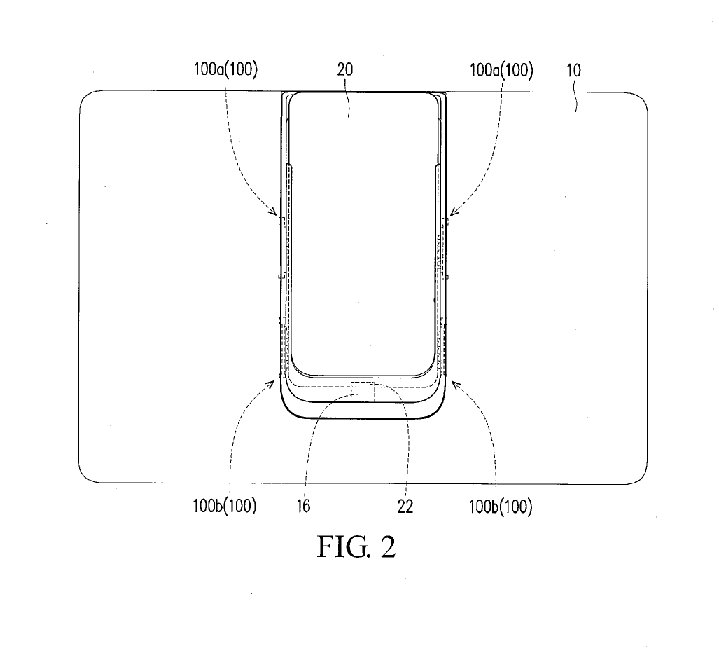

FIG. 1 is an exploded view showing an electronic device in an embodiment of the disclosure. FIG. 2 is a front view showing the electronic device in FIG. 1. Please refer to FIG. 1 and FIG. 2, the electronic device includes a first body 10, a second body 20 and a plurality of clamping components 100, the first body 10 and the second body 20 may be assembled together via the clamping component 100 in the embodiment. In addition, the first body 10 is the electronic device such as a notebook computer, a tablet computer or a mobile phone, which is different from the second body 20 in the embodiment. In the following embodiments, the first body 10 is a tablet computer and the second body 20 is a mobile phone.

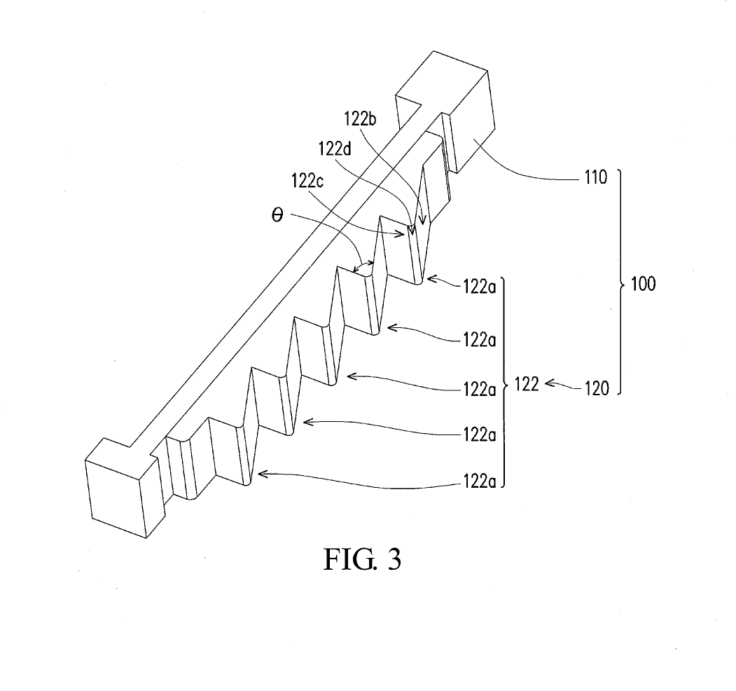

FIG. 3 is a perspective view showing the clamping component in FIG. 1. Please refer to FIG. 1, FIG. 2 and FIG. 3, the first body 10 includes an accommodating space 10a, and the second body 20 can move toward the first body 10 to be received in the accommodating space 10a. The clamping components 100 are symmetrically at the opposite sides of the accommodating space 10a. Each clamping component 100 includes a base 110 and a combining portion 120. The base 110 is at one side of the accommodating space 10a. The combining portion 120 has a obstructing structure 122 and is disposed at the base 110, and the obstructing structure 122 is exposed to the accommodating space 10a.

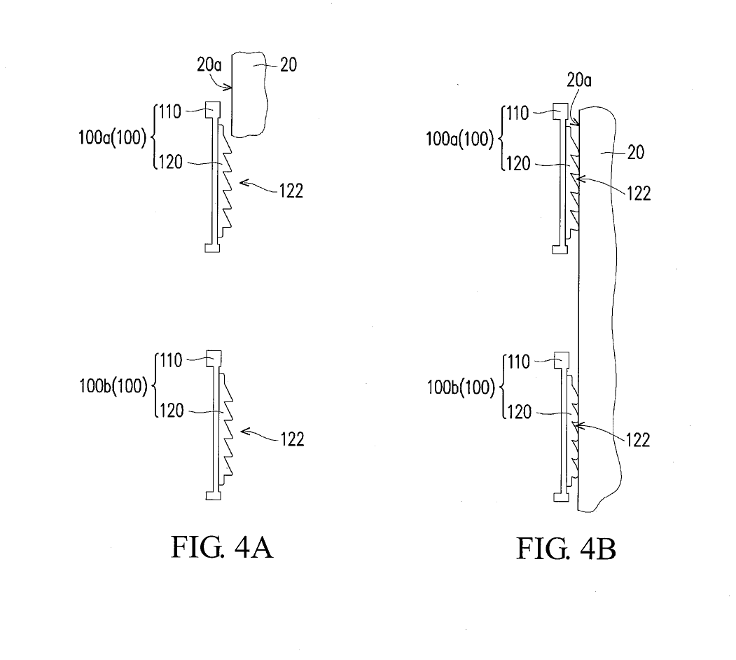

FIG. 4A to FIG. 4B are flowcharts showing the second body and the clamping component are assembled in FIG. 1. It should be noted that for the simplicity of the view, it only shows that the clamping component 100 is at one side of the accommodating space 10a and a part of the second body 20. Please refer to FIG. 1, FIG. 3 and FIG. 4A to FIG. 4B, in detail, when the user slides the second body 20 into the accommodating space 10a from the inlet end 10b of the accommodating space 10a, the two sides 20a of the second body 20 gradually approach the obstructing structure 122 of the clamping component 100 (as shown in FIG. 4A). As the user continuously pushes the second body 20 toward the direction away from the inlet end 10b, the combining portion 120 of the clamping component 100 contacts with the second body 20.

Since the obstructing structure 122 of the combining portion 120 will have an elastic deformation by a thrust, and then it abuts against the side 20a of the second body 20 (as shown in FIG. 4B). Thus, the second body 20 is received in the accommodating space 10a via the clamping component 100 to make the first body 10 and the second body 20 assembled together.

Otherwise, when the second body 20 is moved away from the accommodating space 10a, and the side 20a of the second body 20 is moved away from the combining portion 120 of the clamping component 100, the obstructing structure 122 of the combining portion 120 returns to its original shape by the release of the thrust, so as to facilitate the clamping component 100 to clamp the second body 20 again.

The clamping component 100 of the electronic device 1 can clamp or release the second body 20 via the obstructing structure 122 of the clamping component 100 disposed on the first body 10 to make the first body 10 and the second body 20 combined or separated. Thus, comparing with conventional structures of a hook, a card slot, and a latch, the clamping component 100 can disassemble and assemble the two bodies without affecting the appearance. Therefore, it can maintain the aesthetic of the first body 10 and the second body 20. Further, due to the simple structure of the clamping component 100, it can simplify the combination structure of the first body 10 and the second body 20 to reduce the manufacture cost of the electronic device 1.

Please refer to FIG. 1 and FIG. 3, the obstructing structure 122 of the combining portion 120 in this embodiment has a plurality of convex elements 122a, and a tip of these convex elements 122a face toward a direction away from the inlet end 10b. The obstructing structure 122 of the clamping component 100 is mainly used to provide a frictional force, and the shape of the obstructing structure 122 is not limited to an acute angle, it also may be a bump, which is not limited herein.

In an embodiment, each convex element 122a includes an inclined surface 122b, a bottom surface 122c and a junction surface 122d jointing the inclined surface 122b and the bottom surface 122c, the inclined surface 122b extends toward the direction away from the inlet end 10b and is connected with the junction surface 122d. By this configuration, when the second body 20 slides from the inlet end 10b of the accommodating space 10a and contacts with the combining portion 120 of the clamping component 100, the second body 20 can slide forward into the accommodating space 10a through the leading of the inclined surface 122b, and then it is combined with the first body 10. Thus, it can improve the convenience in assembling the electronic device 1.

Further, the inclined surface 122b of the convex elements 122a moves toward the corresponding bottom surface 122c by the thrust of the second body 20, and the convex elements 122a deform and have an interference with the side 20a of the second body 20, and thus the second body 20 is clamped. In detail, each convex element 122a has a point angle θ which is between the inclined surface 122b and the bottom surface 122c in the extension direction, and the point angle θ may be between 25 degrees to 35 degrees. By this configuration, when the second body 20 is received into the accommodating space 10a, the inclined surface 122b moves toward the bottom surface 122c, so as to facilitate the deformation of the convex elements 122a and reducing the thrust of the second body 20. In addition, the combining portion 120 in this embodiment can be elastically deformed by the force, and thus the material of the combining portion 120 may be an elastic material, such as silicon rubber, and the material of the base 110 may be silicon rubber or plastics.

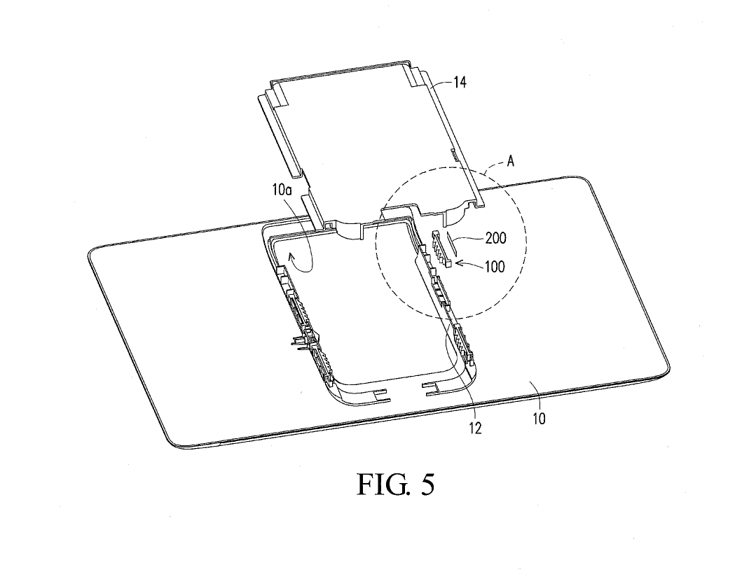

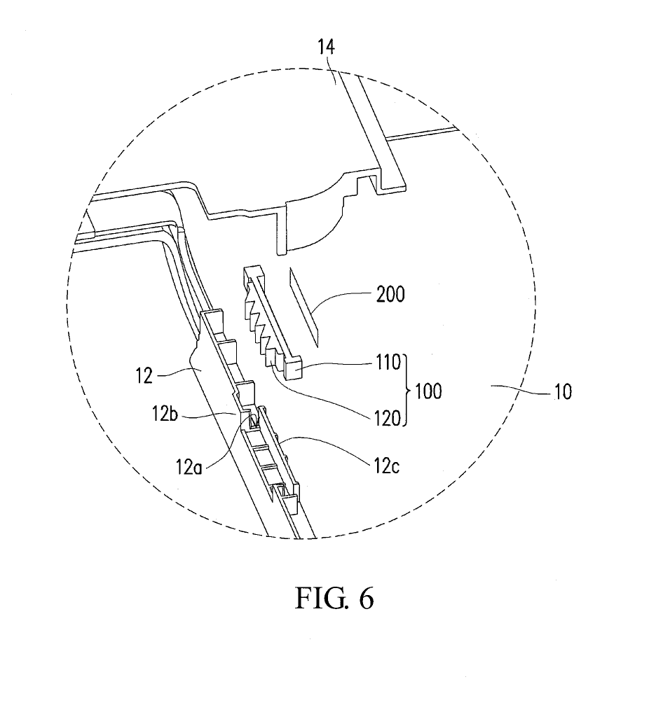

FIG. 5 is an exploded view showing the first body in FIG. 1. FIG. 6 is an enlarged view of a portion A in FIG. 5. For the clearness of the view, the viewing of the first body 10 in FIG. 5 is different from that of the first body 10 in FIG. 1, and a part of the components of the body 10 in FIG. 5 are omitted. Please refer to FIG. 1, FIG. 5 and FIG. 6, the first body 10 in this embodiment includes an annular wall 12 and a bearing plate 14. The accommodating space 10a is formed by the annular wall 12 and the bearing plate 14, and the base 110 of the clamping component 100 is disposed at the bottom of the annular wall 12.

Further, a plurality of the limiting parts 12a conforming to the outline of the base 110 is disposed at the annular wall 12 corresponding to the base 110. Each limiting part 12a includes a first retaining wall 12b and a second retaining wall 12c opposite to each other. After each of the base 110 is installed between the corresponding the first retaining wall 12b and the second retaining wall 12c, the clamping component 100 is assembled at the first body 10. In addition, the electronic device 1 in this embodiment further may include a tape 200 which is disposed between the bottom of the base 110 and the second retaining wall 12c of the annular wall 12. Thus, the risk that the clamping component 100 falls from the first body 10 can be reduced via the adhesion of the tape 200.

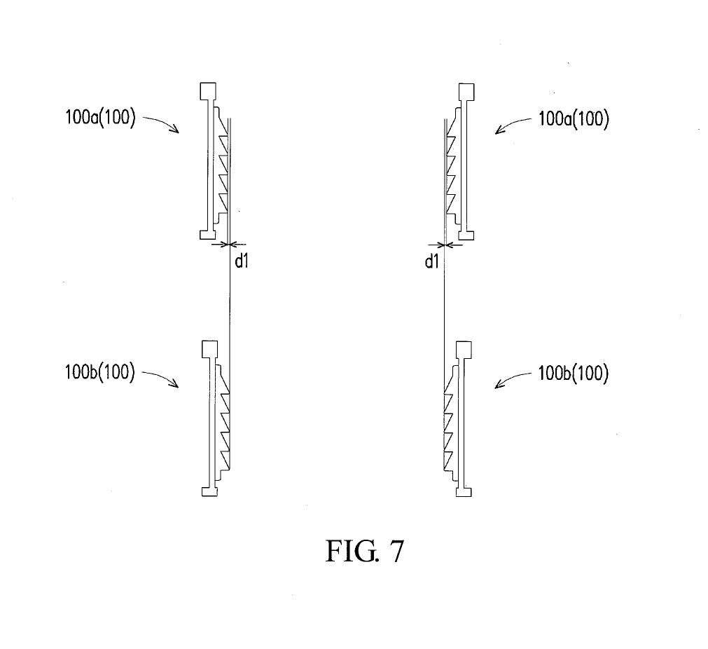

FIG. 7 is a front view showing the clamping component in FIG. 2. Please refer to FIG. 2, FIG. 3 and FIG. 7, the clamping component 100 in this embodiment includes a first part 100a and a second part 100b along the direction away from the inlet end 10b (as shown in FIG. 1). As the second body 20 moves toward the first body 10, the second body 20 passes through the convex elements 122 of the clamping component 100 of the first part 100a and the convex elements 122 of the clamping component 100 of the second part 100b sequentially. The convex elements 122 of the clamping component 100 of the second part 100b protrude a distance dl relative to the first part 100a, respectively, the distance d1 may be between 0.1 mm and 0.3 mm. That means, the interference between the convex elements 122 of the clamping component 100 of the second part 100b and the second body 20 is greater than the interference between the convex elements 122 of the clamping component 100 of the first part 100a and the second body 20. Therefore, it can avoid that the second body 20 is detached from the first body 10 and get broken under an external shock or a sudden vibration. Therefore, it can improve the reliability of the electronic device 1.

Please refer to FIG. 1 and FIG. 2, the first body 10 in this embodiment further includes a plug connector 16, and the second body includes a socket connector 22. The plug connector 16 is opposite to the inlet end 10b. When the second body 10 slides from the inlet end 10b and is received into the accommodating space 10a, the obstructing structure 122 of the combining portion is elastically deformed to against the second body 20, the socket connector 22 and the plug connector 16 are connected. Thus, it can limit the relative movement between the second body 20 and the first body 10. Consequently, it can reduce the risk that the second body 20 is dropped and broken.

In summary, the obstructing structure of the clamping component disposed on the first body can clamp or release the second body of the electronic device to make the first body and the second body combined or separated. Thus, the clamping component make the two bodies disassembled and assembled without affecting the appearance compared to the conventional structures such as a hook, a card slot, or a latch. Therefore, the aesthetic of the electronic device increases. Further, due to the simple structure of the clamping component, it may simplify the combination structure of the first body and the second body to reduce the manufacture cost of the electronic device. Further, when the convex elements of the obstructing structure face toward the direction away from the inlet end, the inclined surface of the convex elements can lead the second body slide forward into the accommodating space, the point angle of the convex elements is between 25 degrees to 35 degrees, therefore, it can improve the reliability of the electronic device. Moreover, the clamping component may be divided into two parts, and the interference between the convex elements of a portion of the clamping component and the second body is greater than the interference between the convex elements of another portion of the clamping component and the second body. Therefore, the risk that the second body detached from the first body under an external shock or a sudden vibration can be reduced.

Although the disclosure has been disclosed with reference to certain preferred embodiments thereof, the disclosure is not for limiting the scope. Persons having ordinary skill in the art may make various modifications and changes without departing from the spirit and the scope of the disclosure. Therefore, the scope of the appended claims should not be limited to the description of the preferred embodiments described above.

What is claimed is:

1. A clamping component adapted to a first body, wherein the first body includes an accommodating space, the clamping component comprising:
a base disposed around the accommodating space; and
a combining portion including a obstructing structure and disposed at the base, wherein the obstructing structure is exposed to the accommodating space, when a second body is received into the accommodating space, the obstructing structure is elastically deformed to against the second body.

2. The clamping component according to claim 1, wherein the second body moves into the accommodating space from an inlet end of the accommodating space, the obstructing structure includes a plurality of convex elements, and the convex elements face toward a direction away from the inlet end.

3. The clamping component according to claim 1, wherein point angles of each of the convex elements is between 25 degrees to 35 degrees.

4. The clamping component according to claim 1, wherein the material of the base is plastics or silicone rubber, and the material of the combining portion is silicone rubber.

5. An electronic device, comprising:
a first body including an accommodating space;
a second body received in the accommodating space;
a plurality of the clamping components symmetrically disposed at opposite sides of the accommodating space, respectively, wherein each of the clamping components includes:
a base disposed around the accommodating space; and
a combining portion including a obstructing structure and disposed at the base, wherein the obstructing structure is exposed to the accommodating space, when the second body is received into the accommodating space, the obstructing structure is elastically deformed to against the second body.

6. The electronic device according to claim 5, wherein the accommodating space includes an inlet end, the second body moves into the accommodating space from the inlet end.

7. The electronic device according to claim 6, wherein the obstructing structure includes a plurality of convex elements, and a tip of the convex elements face toward a direction away from the inlet end.

8. The electronic device according to claim 7, wherein point angles of each of the convex elements is between 25 degrees to 35 degrees.

9. The electronic device according to claim 7, wherein the clamping components include a first part and a second part, the convex elements of the clamping components of the second part protrude a distance relative to the convex elements of the clamping components of the first part, respectively, the distance is between 0.1 mm and 0.3 mm.

10. The electronic device according to claim 5, wherein the material of the base is plastics or silicone rubber, and the material of the combining portion is silicone rubber.
